(19) United States
(12) Patent Application Publication
(10) Pub. No.: US 2006/0156171 A1
(43) Pub. Date: Jul. 13, 2006

(54) Combining spectral shaping with turbo coding in a channel coding system

(75) Inventors: Alexander Vasilievich Kuznetsov, Pittsburgh, PA (US); Erozan Mehmet Kurtas, Pittsburgh, PA (US)

Correspondence Address: David C. Bohn;Westman, Champlin & Kelly, Suite 1600, 900 Second Avenue South, Minneapolis, MN, 55402-3319, US

(73) Assignee: Seagate Technology LLC, Scotts Valley, CA (US)

(21) Appl. No.: 11/012,820

(22) Filed: Dec. 15, 2004

(51) Int. Cl. H03M 13/00

(52) U.S. Cl. 714/755

(57) ABSTRACT

A method of combining spectral shaping with turbo coding in a channel coding system. The method comprises encoding user data with spectrally shaped encoding to provide a suppressed DC user data sector output. The method also comprises generating turbo coded redundant bits for the suppressed DC user data sector. The turbo coded redundant bits are interleaved with additive coding to provide a suppressed DC parity sector.

### FIELD OF THE INVENTION

The present invention relates generally to data communication and storage systems. More particularly, but not by limitation, the present invention relates to encoding and decoding data transmitted through a read/write channel in a data storage device.

### BACKGROUND OF THE INVENTION

Combining different types of encoding/decoding operations, such as spectral shaping coding and turbo product coding for directly decreasing bit error rates, is a technical problem facing design engineers of data communication and storage systems. Although there are simple solutions that have been proposed, these simple solutions do not satisfy technical specifications since the combining leads to degradation of either spectral properties or bit error rates. Selecting and combining the two types of algorithms so that they are compatible with one another is a difficult design task. Known iterative solutions are complex and provide users with sub-optimal performance tradeoffs in bit error rate (BER) and complexity/latency in encoders and decoders. A low complexity combination of encoding/decoding is needed to provide an improved combination of BER and latency.

Embodiments of the present invention provide solutions to these and other problems, and offer other advantages over the prior art.

### SUMMARY OF THE INVENTION

Disclosed is a method of combining spectral shaping with turbo coding in a channel coding system. The method comprises encoding user data with spectrally shaped encoding to provide a suppressed DC user data sector output. The method also comprises generating turbo coded redundant bits for the suppressed DC user data sector. These redundant bits are again encoded using additive coding to provide a suppressed DC parity subsector.

In one preferred embodiment, a channel encoder receives user data, and the channel encoder comprises a first encoder that encodes the user data with spectrally shaped encoding to provide a suppressed DC user data sector output. The channel encoder also comprises a turbo product encoder that generates redundant parity bits for the suppressed DC user data sector. The channel encoder also comprises an interleaver coupled to the turbo product encoder that interleaves the parity bits prior to additive coding providing a suppressed DC parity sector.

In another preferred embodiment, a detection scheme receives suppressed DC data that includes a user data sector and a parity sector that comprises redundant coded bits. The detection scheme comprises a channel detector that receives the input signal, and a decoder for a channel code such as a turbo code. The channel detector provides a first detector output that includes log likelihood ratios of user data sector. The channel detector also provides a second detector output that includes log likelihood ratios of the parity sector. The channel decoder also comprises a turbo product decoder that produces turbo-decoded user data. The channel decoder also comprises a first reverse interleaver that receives the first detector output and that provides the user data sector to the turbo product decoder. The channel decoder also comprises a second reverse interleaver that receives the second detector output and that provides a second reverse interleaver output. The channel decoder also comprises a log likelihood ratio converter that receives the second interleaver output and that provides the parity sector to the turbo product decoder.

Other features and benefits that characterize embodiments of the present invention will be apparent upon reading the following detailed description and review of the associated drawings.

### BRIEF DESCRIPTION OF THE DRAWINGS

FIG. 1A is an isometric view of a disc drive.

FIG. 1B is a block diagram illustrating the architecture of a read/write channel.

FIGS. 2A, 2B illustrate the structure of a two-dimensional turbo product code (TPC) with single (FIG. 2A) and multiple (FIG. 2B) parities per row and column.

FIG. 3 illustrates a block-diagram of the encoder with combined turbo product code and spectral shaping code (TPC+SSC) encoding using with multiple code matrices and separate interleavers for data and parity bits.

FIG. 4 illustrates a block diagram illustrating sequential implementation of encoding operations for the multiple TPC matrices.

FIG. 5 illustrates a block diagram of an iterative decoder with an LLR converter for calculation of soft decisions regarding parity bits of a TPC.

FIG. 6 illustrates a block diagram of an iterative detection using a modified TPC decoder performing parity LLR conversion internally (without a separate LLR converter).

FIG. 7 illustrates a block diagram of an iterative detection scheme with parallel modified TPC decoders and two pairs of interleavers for data and parity sectors.

FIG. 8 illustrates a block diagram of an iterative detection scheme with a serial implementation of a modified TPC decoder and two pairs of interleavers for data and parity sectors.

FIG. 9 illustrates a block diagram of an iterative detection scheme with a serial implementation of the modified TPC decoder and one pairs of interleavers for data sector.

FIGS. 10A, 10B, 10C illustrate definitions of a row of vertical parities and a column of horizontal parities and their concatenation for transmission through a channel.

FIG. 11 illustrates the definition of a syndrome and establishes the relationship between the syndrome and the flag of an additive code word.

FIG. 12 illustrates a block diagram of an algorithm for an internal estimation of a flag value from the intermediate soft decisions.

FIG. 13 illustrates a block diagram of a modified TPC decoder with an internal estimation of a flag value from intermediate soft decisions.

FIG. 14 is an illustrative example of the magnitude of the spectral density of the proposed iterative TPC scheme with a random additive SSC code used in data sector and a structured additive SSC codes used in parity sector.

FIG. 15 is an illustrative example of the magnitude of the spectral density of the proposed iterative TPC scheme with the conventional SSC code used in data sectors and the structured additive SSC codes used in parity sectors.

FIG. 16 is an illustrative example of BER versus SNR characteristics of a perpendicular magnetic recording channel with the generalized PR (GPR) target of length 4 and the cut-off frequency of preamplifier 1/200 of the baud rate.

FIG. 17 is an illustrative example of BER versus SNR characteristics of the perpendicular magnetic recording channel with the full DC PR2 target [1 2 1] and the cut-off frequency of preamplifier 1/200 of the baud rate.

FIG. 18 is an illustrative example of BER versus SNR characteristics of the perpendicular magnetic recording channel with the full DC PR2 target [1 2 1] and the cut-off frequency of preamplifier 1/1000 of the baud rate.

### DETAILED DESCRIPTION OF ILLUSTRATIVE EMBODIMENTS

Iterative soft and hard decoding of turbo-product codes (TPC) used in partial-response (PR) channels uses spectral shaping of signals, for example, by the suppression of an imbalance of zeros and ones in a coded binary stream.

Various types of iterative detection schemes operating with soft decisions regarding transmitted data are known for communication channels and storage systems. These schemes can use a convolutional code, a Low Density Parity Check (LDPC) code or a Turbo-Product Codes (TPC) to add redundant parity bits to the original data and employ them at the receiver side. Combined with a soft channel detector, for example, using the BCJR (Bahl, Cocke, Jelinek and Raviv) algorithm or the Soft-Output Viterbi Algorithm (SOVA), those codes provide flexible tradeoffs in complexity and Bit Error Rate (BER). Despite the increased latency of the decoding process, such iterative detection schemes are the attractive solutions for designing advanced communication systems and high-density magnetic recording applications.

In optical and magnetic storage systems, as well as in some communication systems, first the data are usually encoded by an outer Error Correcting Code (ECC), then sent to a modulation encoder, and finally go to a channel encoder of one of the types mentioned above. The modulation encoder could be of the Run Length Limiting (RLL) type, the Running Digital Sum limiting (RDS) type or the Direct Current Free (DCF) type. The primary task of the modulation code is to facilitate the operation of the front-end stages of the channel, such as a preamplifier, a timing circuit, an equalizer and others. In this application, these types of codes are called Spectral Shaping Codes (SSC). An SSC modifies the distance properties of the output code words of the channel, and therefore can also improve the Bit Error Rate (BER) and Sector Failure Rate (SFR) characteristics of the system, but the primary task of an SSC is to create the necessary structure of an encoded bit stream, for example, by preventing imbalance of zeros and ones that results in a DC content of an analog signal. At the same time, the primary task of a channel code, such as an LDPC code or a TPC, is to guarantee the required BER and SFR characteristics of the channel. Combining these two different types of codes in one system is a non-trivial problem requiring consideration of multiple factors.

An iterative detection scheme based on a TPC requires the use of an interleaver (permuter) at the output of the TPC decoder to produce the BER and SFR characteristics which are comparable with the BER an SFR characteristics of turbo codes and random LDPC codes. But an interleaver changes the order of the already SSC-coded bits and, as a result, nullifies the operation of the SSC-encoder. Since an SSC-encoder based on a finite state machine transforms the data bits using mapping tables without a special structure, the use of such codes in channels with interleaving of coded bits is impossible or severely restricted, especially, when they are applied for encoding of parity bits generated earlier by a TPC or an LDPC encoder. The iterative read/write channel describe below suppresses DC-content in the coded signal by using an arbitrary SSC in the data sector and a subclass of SSC codes known as additive codes in the parity sector. Using an arbitrary SSC in the parity sector is possible, but requires a conversion of soft decisions regarding the parity bits.

When an additive SSC is used in the data subsector, a sequence of matching patterns is chosen from the predefined set and added component wise modulo q to the original data. To identify the matching patterns at the receiver side, a sequence of flags is sent to the receiver. Each flag uniquely defines the pattern, and allows the decoder to perform the reverse operation. During the iterative decoding process the flags are treated by the channel and TPC decoders exactly as all other coded bits, and only at the final step when all decoding iterations are completed, then an SSC decoder uses them to convert SSC coded data bits to the original data.

At the same time, when an additive SSC is used in the parity subsector, again a sequence of matching patterns is chosen from the predefined set and added component wise modulo q to the parity bits of the TPC encoder. But now the flags are involved in the iterative decoding process, and are to be estimated at the intermediate decoding steps. Although the flags are sent to the receiver, and the soft decisions regarding flags are supplied to a TPC decoder by a channel detector, additional more reliable decisions are required to achieve the best BER. For this purpose a method of flag estimation is disclosed called automatic flag detection based on syndromes.

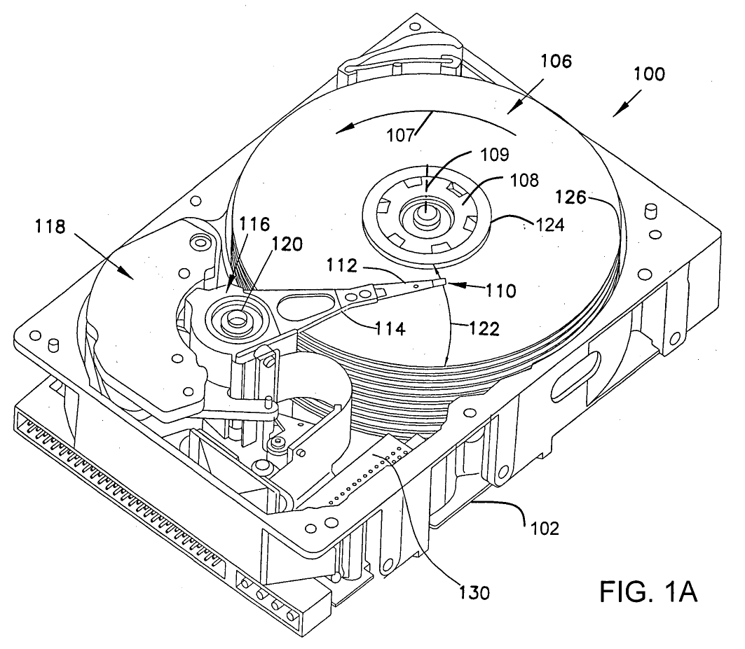

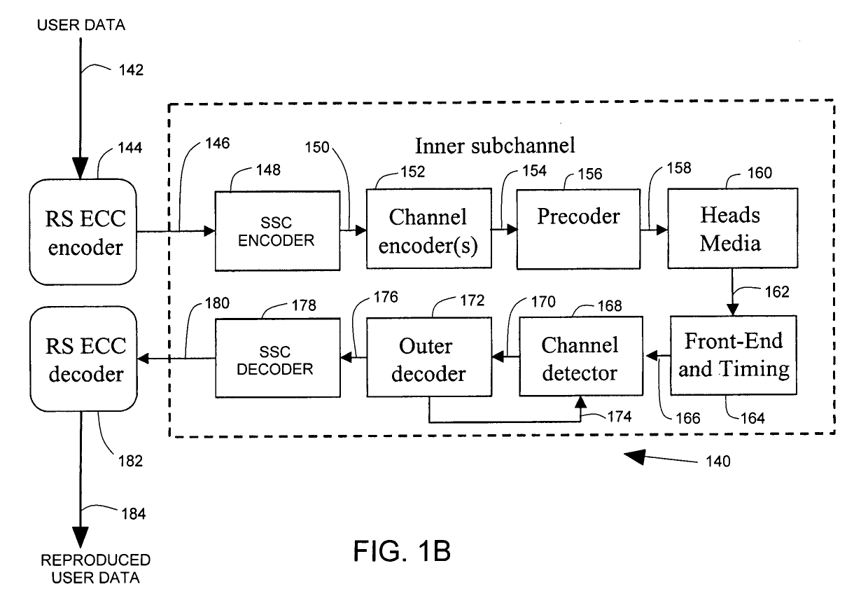

A single error in the received sequence can trigger generation of wrong states in the SSC decoder, and in result can produce a long sequence of output errors. This phenomenon is called error propagation, and often related to an SSC constructed from finite-state machines. For the purpose of limiting error propagation, decoding can be implemented via a sliding-block decoder. But when an additive SSC code is used in both data and parity sectors, a local simple error correcting code can be used to protect flags, and by this way the error propagation in the SSC decoder is reduced drastically. For example, in almost all practical cases a short Hamming code will suffice. The use of a local ECC for the suppression of error propagation is also disclosed. An example described below in connection with FIG. 1A illustrates an exemplary disc drive application for the presently disclosed system that combines spectral shaping coding with turbo coding.

FIG. 1A is an isometric view of a disc drive 100 in which embodiments of the present invention are useful. Disc drive 100 includes a housing with a base 102 and a top cover (not shown). Disc drive 100 further includes a disc pack 106, which is mounted on a spindle motor (not shown) by a disc clamp 108. Disc pack 106 includes a plurality of individual discs, which are mounted for co-rotation about central axis 109 in a direction indicated by arrow 107. Each disc surface has an associated disc head slider 110 which is mounted to disc drive 100 for communication with the disc surface. In the example shown in FIG. 1A, sliders 110 are supported by suspensions 112 which are in turn attached to track accessing arms 114 of an actuator 116. The actuator shown in FIG. 1A is of the type known as a rotary moving coil actuator and includes a voice coil motor (VCM), shown generally at 118. Voice coil motor 118 rotates actuator 116 with its attached heads 110 about a pivot shaft 120 to position heads 110 over a desired data track along an arcuate path 122 between a disc inner diameter 124 and a disc outer diameter 126. Voice coil motor 118 is driven by servo electronics 130 based on signals generated by heads 110 and a host computer (not shown).

FIG. 1B is a block diagram illustrating the architecture of a read/write channel 140 of a magnetic, optical or MRAM storage device in which the embodiments of the present invention can be implemented. User data 142, typically provided by a host computer system (not illustrated) is received by Reed-Solomon error correction code (RS ECC) encoder 144. An output 146 of RS ECC encoder 144 couples to an input of a spectral shaping code (SSC) encoder 148. An output 150 of the SSC encoder 148 couples to a channel encoder 152. An output 154 of the channel encoder 152 couples to a precoder 156. A write output 158 of the precoder 156 couples to a write head in a media channel 160. The media channel 160 includes a read/write head and data storage media. The media channel 160 includes a read head that provides a read output 162 to a front-end and timing circuit 164. The front-end and timing circuit 164 provides filtering and synchronization for the read output 162. An output 166 of the front-end and timing circuit 164 couples to a channel detector 168. An output 170 of the channel detector 168 couples to an outer decoder 172. A feedback path 174 from the outer decoder 172 to the channel detector 168 provides for iterative decoding. An output 176 of the outer decoder 172 couples to an SSC decoder 178. An output 180 of the SSC decoder 178 couples to an RS ECC decoder 182. The RS ECC decoder 182 provides a reproduced user data output 184. The reproduced user data output 184 typically couples back to the host computer system.

The various circuits shown in the blocks of FIG. 1B can be implemented as integrated circuits, discrete components, or suitably programmed processing circuitry. The circuitry relates mainly to the combination of an SSC-encoder, a channel/TPC/encoder and corresponding decoders at the receiver side.

Turbo product code is defined by a multidimensional array of codewords from linear block codes, such as parity check codes, Hamming codes, BCH codes, etc.

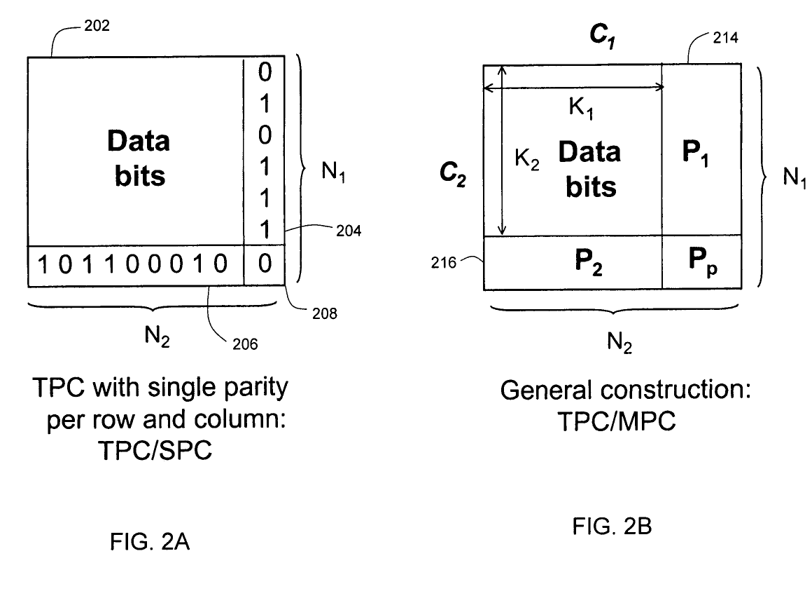

FIGS. 2A-2B illustrates the structure of a two-dimensional TPC. In FIG. 2A, the simplest type of TPC codes is a two-2-dimensional TPC with a single-parity bit per row and column (TPC/SPC). In FIG. 2A, the data bits 202, the row parity bits 204 and the column parity bits 206, and a corner check bit 208 are illustrated in a single parity check TPC. As shown in FIG. 2B, a TPC with multiple parities (TPC/MPC) are similar to the TPC/SPC codes with the exception that there are multiple row parity bits 214 and multiple column parity bits 216. The multiple parity bits provide more flexibility in code structure, code rate and code length. In general, 2-dimensional multi-parity turbo product codes (TPC/MPC) are constructed from two linear binary block codes C₁ and C₂ with parameters (n₁,k₁,d₁) and (n₂,k₂,d₂), where (nᵢ,kᵢ,dᵢ,i=1,2, . . . ) are the codeword length, user data block length and minimum distance, respectively. A 2-dimensional turbo product code C=C₁×C₂ has parameters (n,k,d), where n=n₁·n₂, k=k₁·k₂, and d≧d₁d₂. Its generator matrix is the Kronecker product of the generator matrices of its component codes. In the case of TPC/SPC, each row and each column satisfies a single-parity check, and the minimum distance for an m-dimensional TPC/SPC is 2 m. For applications in data storage systems, 2-dimensional TPC/SPC and TPC/MPC codes are preferred for the sake of higher rates. This is important, since the code rate loss in data storage systems is hard to compensate if the code rate is not high enough. Further, both row and column codes of a TPC code should be chosen the same to save hardware cost in a real implementation.

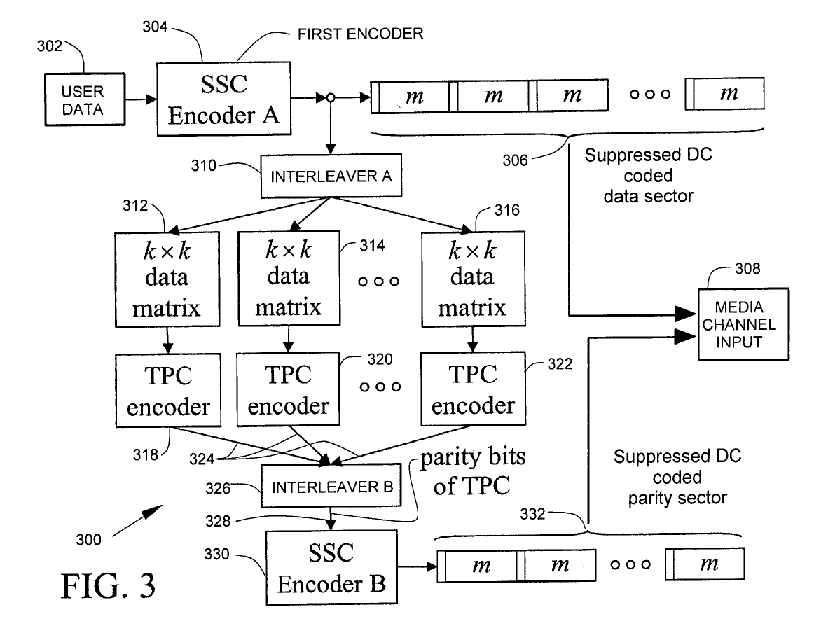

In FIG. 3, a block diagram of a combined TPC+SSC encoder circuit 300 is shown. In the subsequent descriptions it is assumed that a TPC with a single parity bit per row and column is used. The user data 302 is encoded by a SSC-encoder “A” 304, also called first encoder 304, and then encoded user data 306 is coupled to a channel input 308. The SSC-coded bits of the encoded user data 306 are also called the SSC-coded data sector. The output 306 of the SSC-encoder “A” 304 also couples to an interleaver “A” 310 that changes the order of the incoming bits, partitions the output sequence on N subsequences 312, 314, 316 of the size k×k, and arranges each of the subsequences 312, 314, 316 in the form of a square matrix with k rows and k columns.

FIG. 3 shows a parallel processing implementation of the encoding process in which N parallel TPC encoders 318, 320, 322 are used simultaneously to generate parity bits 324 that include a row of column parity bits and a column of row parity bits for each of the k×k matrices 312, 314, 316 mentioned above (see also the example illustrated in FIG. 2A). The row parity bits and the column parity bits are also called the horizontal and vertical parity bits, respectively. In the encoding scheme shown in FIG. 3. All horizontal and vertical parity bits are sent to an interleaver “B” 326, and after the interleaving or permuting process in interleaver “B” 326, an interleaver output 328 is coupled to an input of an SSC encoder “B” 330, also called second encoder 330 the second encoder 330 generates SSC-coded parity bits 332 that are also called the SSC-coded parity sector 332. The SSC-coded parity sector 332 is coupled to the media channel 308.

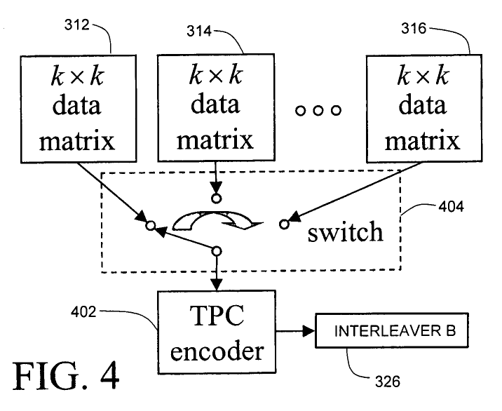

FIG. 4 shows an alternative sequential implementation that can be used in place of the parallel encoding process illustrated in FIG. 3 when only one TPC encoder 402 is used to generate all horizontal and vertical parity bits. A sequencing switch 404 is coupled between the data matrices 312, 314, 316 and the interleaver “B” 326. In FIG. 4, all N data arrays 312, 314, 316 are accessed sequentially, and the generated horizontal and vertical bits are placed in an output buffer under the control of the interleaver “B” 326. Various hybrid “sequential-parallel” implementation of the TPC encoding can be used as well when the number of hardware TPC encoders is greater than one but less than N.

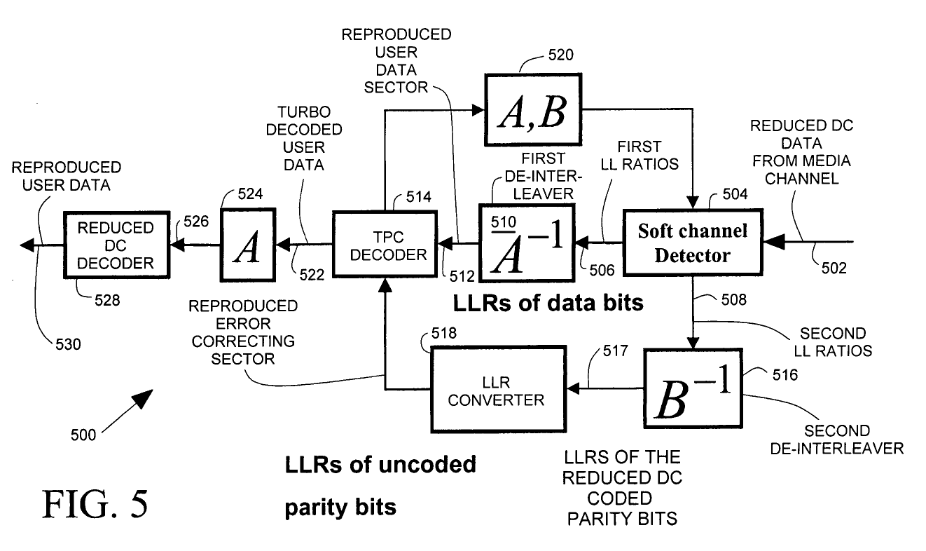

FIG. 5 illustrates a block diagram of a “receiver side” or decoder 500 corresponding with the TPC+SSC encoders shown in FIGS. 3-4. At the receiver side, the received signal is first processed by front end circuits (not illustrated in FIG. 5), sampled, equalized and coupled along line 502 to a channel detector 504 operating with soft input and output decisions. The channel detector 504 can be, for example, a SOVA type or BCJR type of channel detector. A soft decision regarding a specific bit “u” is a real number, and often is a Log-Likelihood Ratio (LLR) which is defined as the probability ratio λ=Pr{u=1}/Pr{u=0}. In some applications it is more convenient to use log λ as a soft decision. In FIG. 5, the input 502 to the channel detector 504 comprises both the encoded data sector and encoded parity sector as explained above in connection with FIG. 3. Therefore, the channel detector 504 produces two groups of soft decisions, i.e., the LLRs regarding the coded data sector and the LLRs regarding the encoded parity sector, called for simplicity the data LLR and the parity LLR. The channel detector 504 generates first LL ratios 506 for the data LLR, and the channel detector 504 generates second LL ratios 508 for the parity LLR.

The data LLR ratios 506 are de-interleaved (de-permuted) exactly as the corresponding data bits by a reverse interleaver A⁻¹ 510, and are coupled along line 512 to an LLR data matrix (not illustrated in FIG. 5) in a soft TPC decoder 514. At the same time, the parity LL ratios 508 couple to a second de-interleaver B⁻¹ 516. The second de-interleaver 516 provides a de-interleaver output 517 which provides de-interleaved LLRs of coded parity bits. The TPC decoder 514 needs the LLRs regarding the original parity bits which have been converted to a format usable by the TPC decoder 514. The conversion of the parity LLRs is done by an LLR converter circuit 518. With this conversion, a conventional TPC decoder 514 can be used to update its input LLRs regarding both data and parity bits. When multiple channel decoding iterations are used, then the updated data and parity LLRs are interleaved again before to be sent to the channel soft decoder as new a priori information. These permutations correspond with the bit permutations A and B performed at the encoding side (FIGS. 3-4), but at the decoding side the permutations are performed on the corresponding LLRs. The TPC decoder 514 operates iteratively with the interleaver block A,B 520. The TPC decoder 514 provides an output 522 that couples to an interleaver A 524. The output 522 includes the information needed to reproduce the user data, however, additional processing steps are used to place the data in the correct format. The interleaver A 524 provides an interleaver output 526 to a suppressed DC (also called DC-free or DCF) decoder 528. The decoder 528 provides reproduced user data 530.

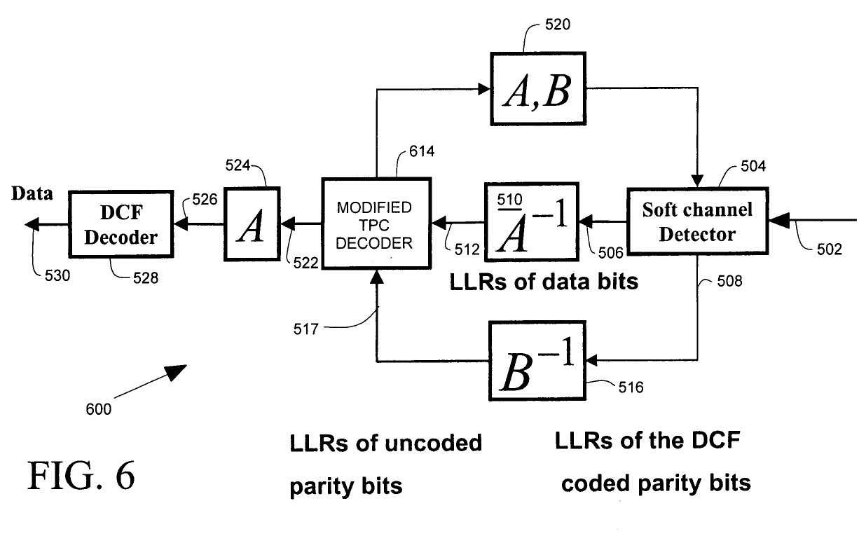

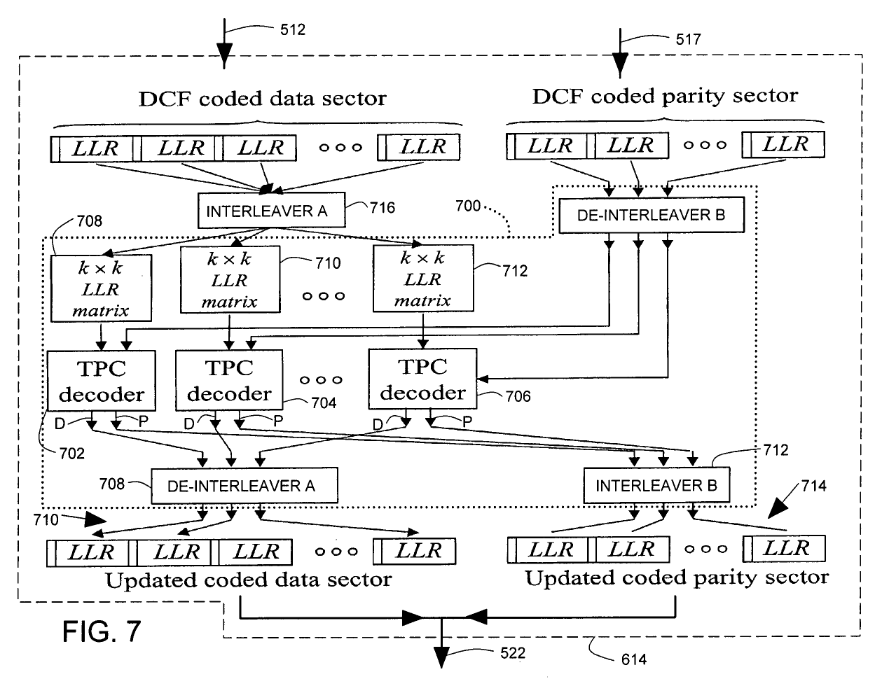

FIG. 6 shows an implementation of an iterative decoder 600 without an LLR converter 518 used in FIG. 5. This scheme uses a modified TPC decoder 614 performing LLR conversions internally. Reference numbers used in FIG. 6 that are the same as reference number used in FIG. 5 identify the same or similar features. In other respects, the decoder 600 of FIG. 6 and the decoder 500 of FIG. 5 are similar. An example of a modified TPC decoder such as TPC encoder 614 is described in more detail below in connection with FIG. 7.

FIG. 7 shows a block diagram of an example of an internal structure of the TPC decoder 614 in FIG. 6. Separate hardware circuits are used for updating a data LLR array (received from line 512) and a parity LLR array (received from line 517). These parallel circuits are shown in FIG. 7 as a plurality of the TPC decoders 702, 704, 706 with each TPC decoder having multiple inputs coupling to the corresponding data and parity LLR arrays. Since the decoder shown in FIG. 7 does not assume the use of a separate LLR converter 518 for parity bits (such as in FIG. 5), the TPC decoders 702, 704, 706 are modified in such a way that the LLRs of SSC-coded parity bits (from line 517) can be used as the inputs of a TPC decoder. The detailed description of the modifications are described below.

Each parallel TPC decoder 702, 704, 706 has two updated outputs data (D) and parity (P). All updated data LLRs (D) are coupled to a de-interleaver (de-permuter) A⁻¹ 708, and the de-interleaver 708 provides the updated data sector 710 of LLRs. All updated parity LLRs (P) are coupled to the interleaver B 712, and the interleaver B 712 provides the updated parity sector 714 of LLRs. The updated data and parity sectors of LLRs are returned to the channel detector (via block A,B 520 in FIG. 6) and used as a priori information in a subsequent channel iteration.

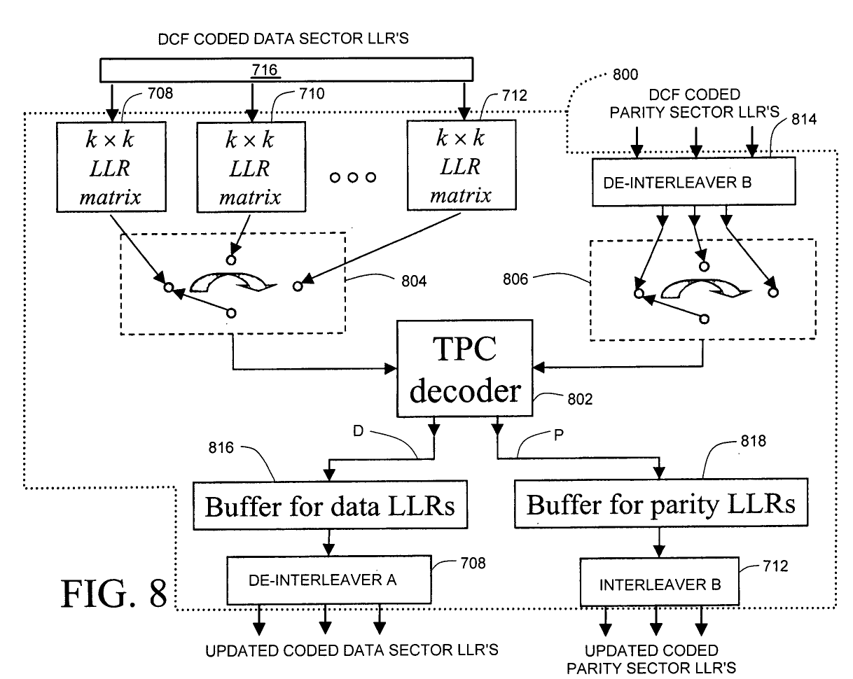

FIG. 8 illustrates a circuit 800, that has a single TPC decoder 802, and that can be used to replace the circuit 700 ( FIG. 7), that has multiple TPC decoders. Reference numbers used in FIG. 7 that are the same as reference numbers used in FIG. 7 identify the same or similar features. Two switches 804, 806 are used to connect the TPC decoder 802 to the data LLR matrices 708, 710, 712, and the de-interleaver B 814 of the parity LLR circuitry. When the interleaver B (part of block 520, FIGS. 5, 6) is used at the encoding side of the channel, then de-interleaver B 814 (FIG. 8) is used to place the received parity LLR at their original positions. Since the updated data and parity LLRs corresponding to the different LLR matrices are generated sequentially, then a couple of memory buffers 816, 818 are used to accumulate the updated data and parity sectors of LLRs before the final permutations in blocks 708, 712.

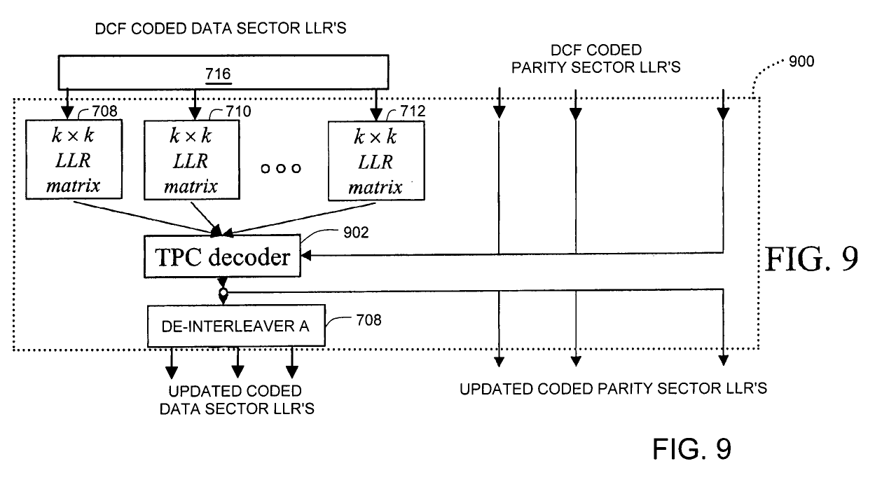

FIG. 9 illustrates a circuit 900, that has a single TPC decoder 902, and that can be used to replace the circuit 700 ( FIG. 7), that has multiple TPC decoders. Reference numbers used in FIG. 9 that are the same as reference numbers used in FIG. 8 identify the same or similar features. FIG. 9 illustrates a simplified implementation of the TPC+SSC scheme using only one TPC decoder 902 and one interleaver A 716 and one de-interleaver A⁻¹ 708. The TPC decoder 902 is modified to accept the DCF coded parity sector LLRs. A simulation test of the circuit shown in FIG. 9 shows that FIG. 9 provides superior BER and spectral characteristic performance.

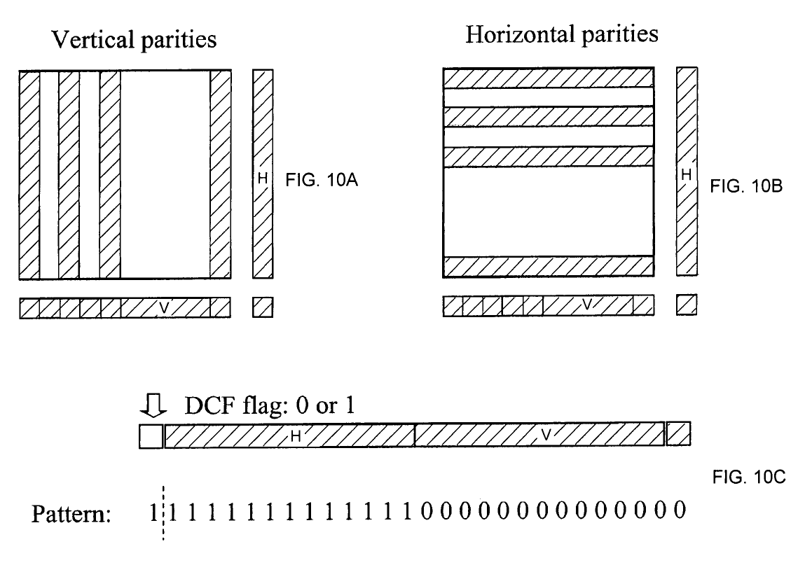

Implementation of vertical and horizontal updates in the modified TPC decoder are described below in connection with FIGS. 10A, 10B, 10C. A conventional soft TPC decoder uses the Message Passing Algorithm (MPA) for updating LLRs of the binary words satisfying parity check equations. For the TPC code, such parity check equations are satisfied for all rows and columns of the coded matrices described above in connection with FIGS. 2A, 2B. In other words, for each row and column, the modulo 2 sum of all bits is always equal to zero. But an SSC-encoder changes some parity bits and, as a result, can violate some parity check equations, i.e., for some columns or rows of the encoded matrix the sum of bits will be equal to 1. In such situations the conventional TPC decoder produces wrong results, but the modified TPC decoder accepts the LLRs of the SSC coded bits by using an additive SSC code for encoding parity bits.

A simple additive code uses a special matching binary pattern \overline{c} and can add it to the uncoded binary word when the circumstances require such addition. The choosing of matching patterns and the additive coding scheme are known to those skilled in the art. It is important, however, that the additive code word is either the word \overline{u} consisting of all zeros flag followed by the data bits, or the component-wise sum modulo 2 of the word \overline{u} and the matching pattern \overline{c}. The structure of the matching pattern used for the SSC-encoding of the parity bits at the output of the TPC decoder is shown in FIG. 10C. This matching pattern contains symbol “1” at all positions corresponding to the positions of the horizontal parities, and symbol “0” at all positions corresponding to the positions of the vertical parities.

If an additive SSC code is used in the data sector, i.e., in the SSC encoder A in FIG. 3, then there is no constraint on the structure of the matching pattern, for example, it can be generated by a random choice. The modified TPC decoder for the proposed TPC+SSC scheme without a separate LLR converter uses the matching pattern described above.

In the implementation of the encoding block (FIGS. 3,4), the horizontal and parity bits of the multiple TPC matrices are not spread over the sector. Each column of horizontal parities and a row of vertical parities are converted or represented into a binary word as shown in FIGS. 10A, 10B. When this word is preceded by a zero flag, it can be considered as a word \overline{u} of the additive code. Therefore, the corresponding parity LLRs are received from a channel detector as two consecutive blocks corresponding to the parts “H” and “V” of the additive code word as shown in FIG. 10C.

For encoding parity bits in the additive scheme, a nonzero pattern satisfies the following two conditions:

All components corresponding to vertical parities are set to zero.

All components corresponding to horizontal parities are set to one.

Such a choice of the pattern during DCF coding of parity bits does not modify the vertical parities, and therefore the vertical updates of the LLR can be performed exactly as in the conventional TPC decoder.

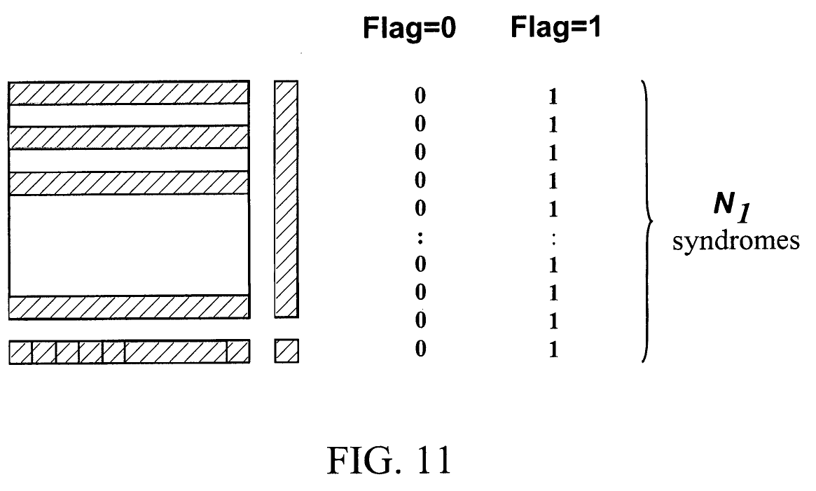

FIG. 11 illustrates Implementation of horizontal updates in the combined TPC+DCF scheme. FIG. 11 illustrates horizontal updates of the LLRs in the implemented TPC scheme. Here, an implementation of the TPC+SSC scheme is considered with the parity bits received from a channel detector as two consecutive blocks corresponding with positions “H” and “V” shown in FIG. 10.

As described above, in the additive coding scheme, a nonzero pattern with all ONES at positions corresponding to horizontal parities is used. This means that if the corresponding flag is equal to one then all vertical parities are complemented (inverted). This can be seen as a switch from even parity check equations to odd parity check equations.

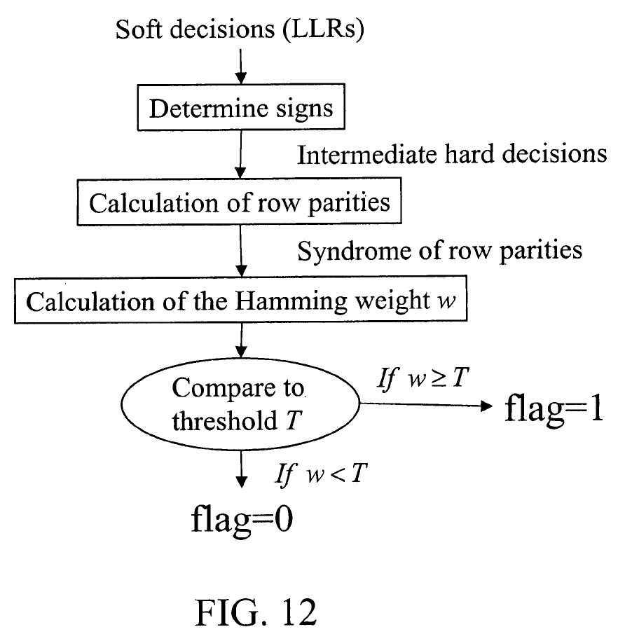

Before the horizontal updates are performed, the type of horizontal parities: “even” or “odd”, should be determined. The hard decision based on the LLR of the corresponding flag can be used for this purpose, but this single hard decision is unreliable when used at the low and moderate values of the SNR. A different method of the automatic flag detection is used as described below in connection with FIGS. 11-12 based on the horizontal syndromes of the coded TPC matrix. FIG. 11 and FIG. 12 illustrate this method. In particular, FIG. 12 shows a flow chart describing the following sequence of operations used for flag detection.

Calculation of the intermediate hard decisions using the input LLRs from the buffer containing initial or current values of input soft decisions.

Calculation of the syndrome containing n modulo 2 sums of the row bits of the hard decisions obtained at the previous step.

Calculation of the Hamming weight of syndrome w, and comparing it with a threshold T. If w<T, then the flag of additive code is set to 0, otherwise the flag is set 1.

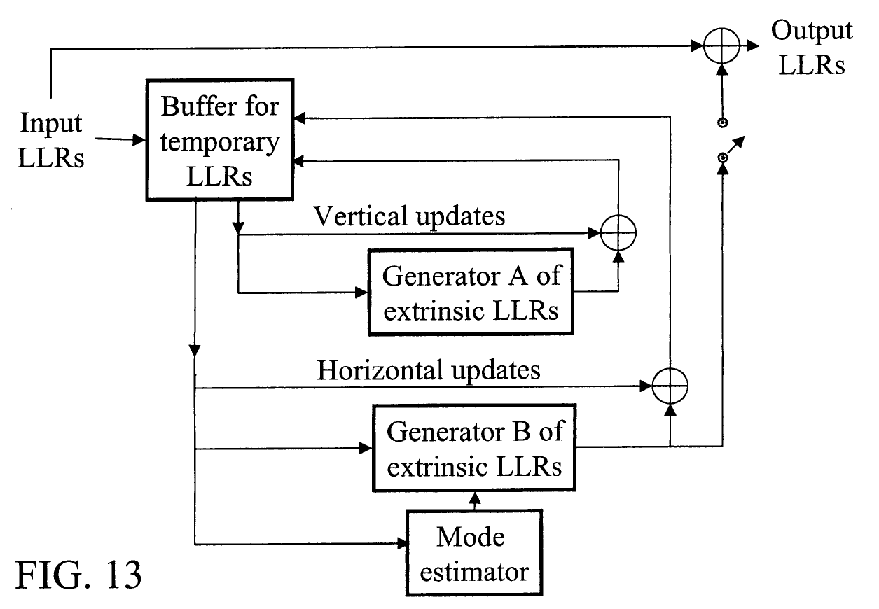

FIG. 13 is a block diagram of the modified TPC decoder with an internal estimation of a flag value from the intermediate soft decisions. During horizontal updates the extrinsic LLR values are first calculated as in conventional TPC decoder, but upon the completion of this first step, the signs of extrinsic values corresponding to horizontal parities are change to the opposite values if the flag determined as described above is equal to one. This operation can be considered as internal LLR conversion.

The TPC decoder performing automatic flag detection and internal LLR conversion is referred to here as the modified TPC decoder.

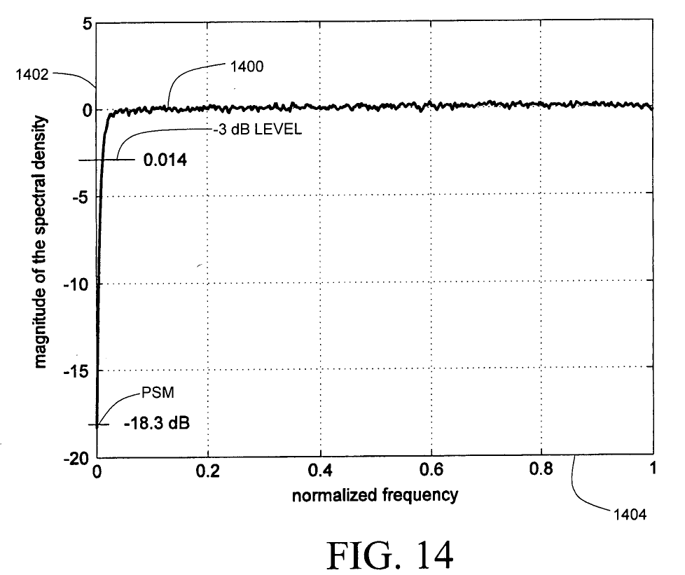

FIG. 14 shows the magnitude of the spectral density 1400 of coded sequences in the designed iterative TPC16+SSC scheme with a random additive SSC code used in data sectors and a structured additive SSC codes used in parity sectors. A vertical axis 1402 represents a magnitude of spectral density and a horizontal axis 1404 represents a normalized frequency.

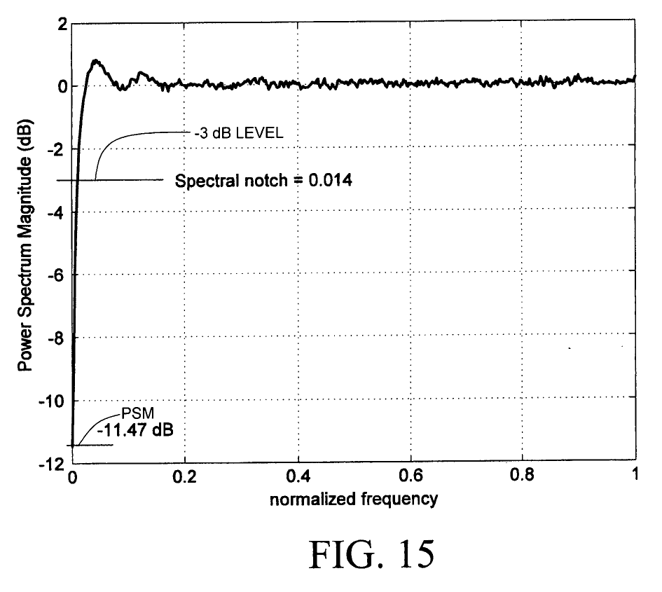

For comparison to FIG. 14, FIG. 15 shows the magnitude of the spectral density of the proposed iterative TPC scheme with the conventional DCF code used in data sectors and the structured additive DCF codes used in parity sectors. As can be seen from FIGS. 14, 15, the use of two additive DCF codes gives much smaller first sample of the PSM, i.e., −18.3 dB compared with −9.0 dB of the conventional DCF code. Both codes have approximately the same spectral width at the level −3.0 dB.

The BER of the proposed iterative TPC+SSC scheme with a random additive SSC code used in data sectors and a structured additive SSC codes used in parity sectors are evaluated by the simulation of all encoding and decoding operation in a software model of a perpendicular magnetic recording system. In simulations the received signal were equalized using a generalized partial response target of length 4 (GPR4) and the full DC PR2 target [1 2 1]. An AC-coupled preamplifier was modeled by the high pass filter with the cut-off frequency set to 1/200 or 1/1000 of the baud rate. The user-normalized linear density (uND) is equal to 2.3, while the channel bit density (cbd) is adjusted according to the code rate R using the formula cbd=uND/R. The signals were generated using 60% of media noise and 40% of electronic noise.

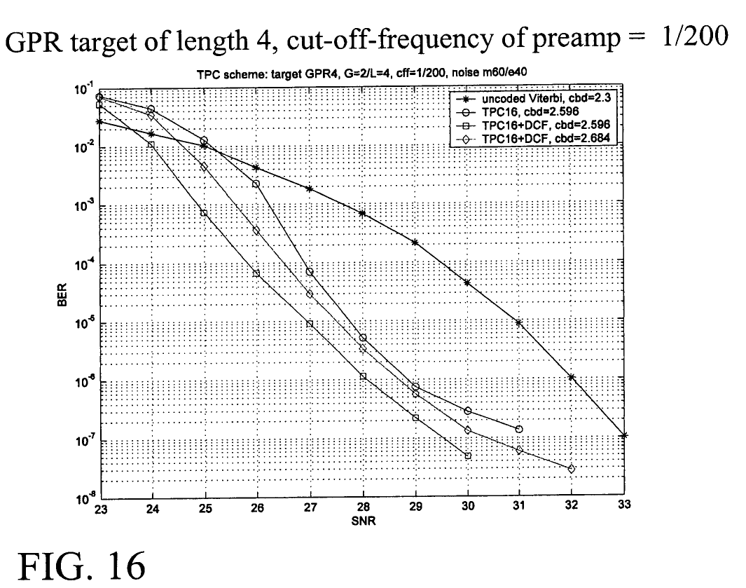

FIGS. 16-18 show the bit error rates (BER) after the DCF decoder versus signal to noise ration (SNR) for the following three systems as indicated by keys in FIGS. 16-18.
The conventional uncoded channel with Viterbi detector operating at cbd=uND=2.3.
The conventional TPC16 scheme with 16 component data matrices of size 16×16 and one parity bit added to each row and column (the coded TPC matrices has the size 17×17, the code rate R≈0.886, cbd=2.596).
The designed TPC16+DCF scheme with 17 component matrices of size 16×16 and one parity bit added to each row and column (again the coded TPC matrices has the size 17×17, the rate of the TPC code R≈0.886, but number of user bits K=4224).

In the designed TPC16+DCF scheme, a random additive DCF encoder with rate 33/34 is used. In this case, the DCF coded data sector consists of 128 additive code words of length 34, and has the length 4352=128*34=17*256. Therefore, the DCF coded data sector fits exactly 17 data matrices of size 16×16. The TPC encoder produces 561=17*33 parity bits sent to the second additive DCF encoder producing additional 17 flag bits. The total length of data and parity sectors is 4930 bits. Therefore, the final code rate R=4224/4930=0.8568, and the channel bit density cbd=2.3/0.8568 =2.6844 when both code rates of TPC and DCF are taken into consideration. In order to estimate the effect of the code rate, the figures also show the BER of the designed TPC16+DCF scheme when only the rate 0.886 of the TPC is used to adjust the channel bit density.

In FIG. 16, the final BER of the perpendicular magnetic recording channel with the generalized PR (GPR) target of length 4 and the cut-off frequency of preamplifier 1/200 of the baud rate. In all iterative TPC schemes the number of global iteration G=2 (here, one global iterations consists of a channel iteration followed by four iterations in the TPC decoder, L=4). This FIG. 16 shows that the designed TPC+DCF scheme preserves the BER of the stand alone TPC scheme even with the optimal equalization to the GPR target, and at the same time operates with well spectrally shaped signals.

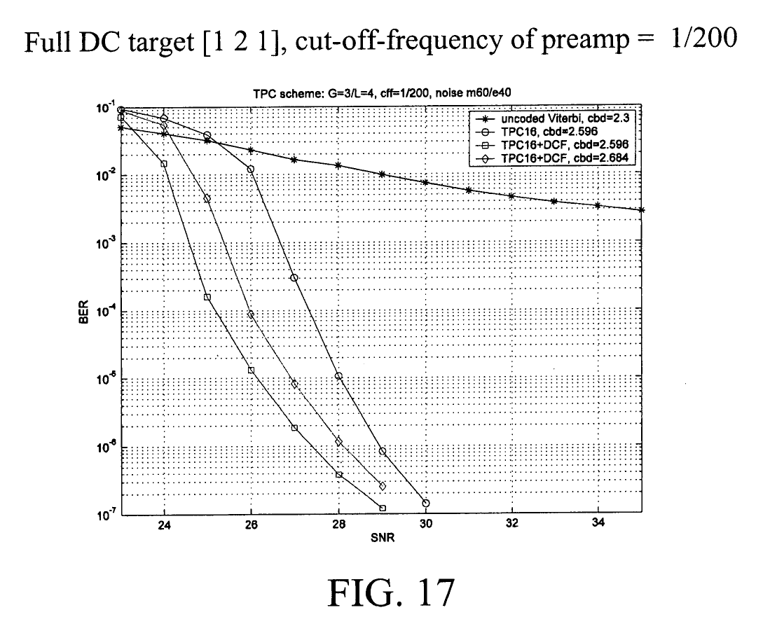

In FIG. 17, the final BER of the perpendicular magnetic recording channel with the full DC PR2 target [1 2 1] and the cut-off frequency of preamplifier 1/200 of the baud rate. This FIG. 17 illustrates the usefulness of the DCF code in the systems where for some reasons the choice of the target is not optimized for a specific front end of a channel.

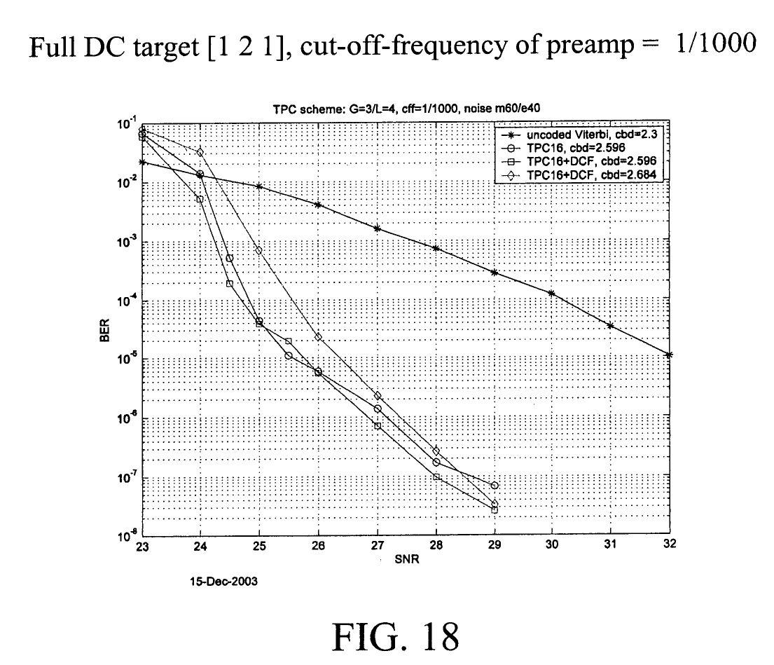

In FIG. 18, the BER of the perpendicular magnetic recording channel with the full DC PR2 target [1 2 1] and the cut-off frequency of preamplifier 1/1000 of the baud rate. In this FIG. 18, it again close BERs are observed for both iterative TPC schemes, but can conclude that the spectral shaping can be achieved without sacrificing the BER characteristics.

The functioning of the individual internal blocks of a sample encoder (such as the encoders illustrated in FIGS. 3, 4) can be verified by applying simulated data test patterns to the sample encoder and also to a software model of the sample encoder and then comparing the encoded outputs of the sample encoder (such as a write current output) and the software model to see if there is a substantial similarity of the comparable encoded outputs. The simulated data test patterns applied to the sample encoder can be provided with artificially high noise margins to reduce random errors, or can be provided with simulated errors to test response of the encoder to errors. When substantially identical results are obtained for both the sample encoder and the software model, this verifies the internal structure of sample encoder is the same as the software model.

The functioning of the individual internal blocks of a sample decoder (such as the decoders illustrated in FIGS. 5-9) can be verified by applying simulated data test patterns to the sample decoder and also to a software model of the sample decoder and then comparing the reproduced decoded outputs of the sample decoder and the software model outputs to see if there is a substantial similarity of the decoded outputs. The simulated data test patterns applied to the sample decoder can be provided with artificially high noise margins to verify functioning of more deterministic blocks such as interleavers and de-interleavers. The simulated data test patterns applied to the sample decoder can also be provided with simulated error patterns to verify functioning of error correction functions. When substantially identical results are obtained for both the sample decoder and the software model, this verifies the internal structure of sample decoder is the same as the software model.

In a preferred arrangement, encoders (such as illustrated in FIGS. 3,4), decoders (such as illustrated in FIGS. 5-9), or both the encoders and decoders can be provided with test outputs or test view modes so that that input and outputs of various internal blocks of circuitry can be observed directly while various data test patterns are applied at inputs. Log likelihood ratio outputs and iterations can be directly observed in test view modes or at test outputs. These test views can be used to provide alternative verification that sample encoders and decoders conform to their respective block diagram models.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application for the iterative coding system while maintaining substantially the same functionality without departing from the scope and spirit of the present invention. It will be appreciated by those skilled in the art that the embodiments described herein can be used with known read heads including magnetoresistive, giant magnetoresistive (GMR), tunneling magnetoresistive (TMR) heads, and can also be used in MRAM systems. In addition, although the preferred embodiment described herein is directed to an iterative coding system for data tracks with concentric round geometries, it will be appreciated by those skilled in the art that the teachings of the present invention can be applied to data tracks or data patterns with other geometries that include spectral shaping and turbo coding, without departing from the scope and spirit of the present invention.

What is claimed is:

1. A method of combining spectral shaping with turbo coding in a channel coding system, comprising:
encoding user data with spectrally shaped encoding to provide a suppressed DC user data sector output;
generating turbo coded redundant bits for the suppressed DC user data sector; and
processing the turbo coded redundant bits with added bits to limit an imbalance of ones and zeros.

2. The method of claim 1 wherein the spectral shaped encoding is repetitively combined with the generating of turbo coded redundant bits.

3. The method of claim 1, further comprising:
generating the spectrally shaped encoding as an outer encoding process; and
generating the turbo coded redundant bits as an inner encoding process.

4. The method of claim 1, further comprising:
generating the suppressed DC parity sector with additive coding.

5. The method of claim 1, wherein the user data is encoded for storage on a data storage device.

6. The method of claim 1, further comprising:
generating log likelihood ratios of a reproduced user data sector and a reproduced parity sector; and
decoding the log likelihood ratios to provide reproduced user data.

7. The method of claim 6, further comprising:
generating the reproduced user data using a turbo product decoder.

8. A channel encoder that receives user data, comprising:
a first encoder that encodes the user data with spectrally shaped encoding to provide a suppressed DC user data sector output;
a first interleaver coupled to the first encoder that interleaves the suppressed DC user sector output;
a turbo product encoder that generates redundant bits for the suppressed DC user data sector; and
a second interleaver coupled to the turbo product encoder that interleaves the redundant bits with additive coding to provide a suppressed DC parity sector.

9. The channel encoder of claim 8 wherein:
the first interleaver generates a plurality of interleaved data matrices; and
the turbo product encoder comprises a plurality of turbo encoders that turbo product encode the interleaved data matrices in parallel with one another.

10. The channel encoder of claim 9 wherein:
a number of the interleaved matrices encoded in parallel is N; and
a number of the turbo encoders performing the encoding in parallel is N.

11. The channel encoder of claim 9 wherein:
a number of the interleaved matrices encoded in parallel is N; and
a number of the turbo encoders performing the encoding in parallel is greater than 1 and less than N.

12. The channel encoder of claim 9, further comprising:
a switch coupling the interleaved data matrices serially to the turbo product encoder.

13. The channel encoder of claim 8 wherein:
the channel encoder further comprises a media channel input;
the first encoder generates a suppressed DC coded data sector that couples to the media channel input; and
the turbo product encoder generates a suppressed DC coded parity sector that couples to the media channel input.

14. The channel encoder of claim 13 wherein the media channel input comprises a write channel input of a data storage device.

15. A channel decoder receiving suppressed DC data including a user data sector and a parity sector, comprising:
a channel detector receiving the data and providing a first detector output that includes log likelihood ratios of user data sector and a second detector output that includes log likelihood ratios of the parity sector;
a turbo product decoder producing turbo-decoded user data;
a first reverse interleaver receiving the first detector output and providing the user data sector to the turbo product decoder; and
a second reverse interleaver receiving the second detector output and providing a second reverse interleaver output including the parity sector to the turbo product decoder.

16. The channel decoder of claim 15, further comprising:
a log likelihood ratio converter receiving the second interleaver output and providing the parity sector to the turbo product decoder.

17. The channel decoder of claim 15 wherein:
the first reverse interleaver generates a plurality of de-interleaved log likelihood ratios of the data sector; and
the turbo product decoder comprises a plurality of turbo decoders that turbo product decode the log likelihood ratios of the data sector.

18. The channel decoder of claim 17 wherein:
a number of the interleaved matrices decoded in parallel is N; and
a number of the turbo decoders performing the decoding in parallel is N.

19. The channel decoder of claim 17 wherein:
a number of the interleaved matrices decoded in parallel is N; and
a number of the turbo decoders performing the decoding in parallel is greater than 1 and less than N.

20. The channel decoder of claim 17, further comprising:
a switch coupling the log likelihood ratio matrices of the data sector serially to the turbo product decoder.
